(19) United States
(12) Patent Application Publication
(10) Pub. No.: US 2026/0006850 A1
(43) Pub. Date: Jan. 1, 2026

(54) ARRAY SUBSTRATE AND DISPLAY PANEL INCLUDING THE SAME

(71) Applicant: WUHAN CHINA STAR OPTOELECTRONICS TECHNOLOGY CO., LTD., Wuhan, Hubei (CN)

(72) Inventors: Zhifu LI, Wuhan, Hubei (CN); Guanghui LIU, Wuhan, Hubei (CN); Fei AI, Wuhan, Hubei (CN); Dewei SONG, Wuhan, Hubei (CN); Zhuang LI, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/249,249

(22) PCT Filed: Mar. 24, 2023
(86) PCT No.: PCT/CN2023/083900

§ 371 Date: Sep. 13, 2025

(30) Foreign Application Priority Data
Jan. 31, 2023 (CN) 202310099805.5

(51) Int. Cl. H10D 30/67; H10D 86/40; H10D 86/60

(52) U.S. Cl. CPC H10D 30/6757; H10D 86/431; H10D 86/471; H10D 86/60

(57) ABSTRACT

The disclosure provides an array substrate and a display panel including the same. The array substrate includes a first cushion layer including a first side slope surface and a second side slope surface disposed opposite to each other, a first transistor including a first semiconductor layer, and a second transistor including a second semiconductor layer. A channel of the first semiconductor layer is partially located on the first side slope surface, a plane of a channel of the second semiconductor layer is parallel to a substrate, and an electron mobility of the first semiconductor layer is greater than an electron mobility of the second semiconductor layer.

### TECHNICAL FIELD

The disclosure relates to the technical field of display, in particular to an array substrate and a display panel including the same.

### BACKGROUND

Integrating integrated circuits on substrates (glass substrates, flexible substrates, etc.) can greatly improve integration of display panels, to reduce manufacturing cost of the display panels. A technology of integrating the integrated circuits on the glass substrates is called system on glass (SOG) technology. However, an electron mobility of conventional thin-film transistors needs to be improved and thin-film transistors with smaller sizes also need to be designed, so as to realize the integration of the integrated circuits on the substrates.

However, existing thin-film transistors controlling sub-pixels have problems of an insufficient electron mobility and too large sizes.

### SUMMARY OF INVENTION

### Technical Problem

Embodiments of the disclosure provide an array substrate and a display panel to solve problems of an insufficient electron mobility and too large sizes in existing thin-film transistors.

### Technical Solution

An embodiment of the present disclosure provides an array substrate, including:
a substrate;
a first cushion layer, disposed on the substrate, and including a first side slope surface, a second side slope surface opposite to the first side slope surface, and a top surface connected between the first side slope surface and the second side slope surface;
a first transistor, including a first semiconductor layer disposed on the first side slope surface, wherein a channel of the first semiconductor layer is partially located on the first side slope surface; and
a second transistor, including a second semiconductor layer, wherein a plane of a channel of the second semiconductor layer is parallel to the substrate;
wherein an electron mobility of the first semiconductor layer is greater than an electron mobility of the second semiconductor layer.

Optionally, in some embodiments of the disclosure, the first transistor as a bottom-gate transistor further includes a first gate electrode that is the first gate electrode.

Optionally, in some embodiments of the disclosure, the channel of the first semiconductor layer is located between a first end and a second end of the first semiconductor layer; the first end is partially located on the substrate, and the second end is partially located on the top surface.

Optionally, in some embodiments of the disclosure, the first transistor further includes a first gate insulating layer, a first source electrode, and a first drain electrode;
the array substrate further includes an interlayer insulating layer, and a layer structure of the array substrate includes:
the first gate insulating layer disposed on the first gate electrode;
the first semiconductor layer disposed on the first gate insulating layer;
the interlayer insulating layer disposed on the first semiconductor layer; an interlayer insulating layer, disposed on the first semiconductor layer that is on the first gate insulating layer; and
the first source electrode and the first drain electrode disposed on the interlayer insulating layer;
a first through-hole and a second through-hole, penetrating the interlayer insulating layer, wherein the first source electrode is electrically connected to the first end through the first through-hole, and the first drain electrode is electrically connected to the second end through the second through-hole.

An embodiment of the disclosure provides a display panel including an array substrate, the array substrate includes:
a substrate;
a first cushion layer, disposed on the substrate, and including a first side slope surface, a second side slope surface opposite to the first side slope surface, and a top surface connected between the first side slope surface and the second side slope surface;
at least one first transistor, including a first semiconductor layer disposed on the first side slope surface, wherein a channel of the first semiconductor layer is partially located on the first side slope surface; and
at least one second transistor, including a second semiconductor layer, wherein a plane of a channel of the second semiconductor layer is parallel to the substrate;
wherein an electron mobility of the first semiconductor layer is greater than an electron mobility of the second semiconductor layer; and
wherein the display panel further includes a high-speed operation module and a low-speed operation module, the high-speed operation module includes a plurality of the first transistors, and the low-speed operation module includes a plurality of the second transistors.

Optionally, in some embodiments of the disclosure, the first transistor as a bottom-gate transistor further includes a first gate electrode that is the first gate electrode.

Optionally, in some embodiments of the disclosure, the channel of the first semiconductor layer is located between a first end and a second end of the first semiconductor layer; the first end is partially located on the substrate, and the second end is partially located on the top surface.

Optionally, in some embodiments of the disclosure, the first transistor further includes a first gate insulating layer, a first source electrode, and a first drain electrode;

the array substrate further includes an interlayer insulating layer, and a layer structure of the array substrate includes:
the first gate insulating layer disposed on the first gate electrode;
the first semiconductor layer disposed on the first gate insulating layer;
the interlayer insulating layer disposed on the first semiconductor layer; and
the first source electrode and the first drain electrode disposed on the interlayer insulating layer;
a first through-hole and a second through-hole, penetrating the interlayer insulating layer, wherein the first source electrode is electrically connected to the first end through the first through-hole, and the first drain electrode is electrically connected to the second end through the second through-hole.

Optionally, in some embodiments of the disclosure, the second transistor further includes a second gate electrode, and the first gate electrode and the second gate electrode are disposed in a same layer.

Optionally, in some embodiments of the disclosure, the second transistor is a top-gate transistor.

Optionally, in some embodiments of the disclosure, the second transistor further includes a second gate insulating layer, a second source electrode, and a second drain electrode;
a layer structure of the array substrate further includes:
the second semiconductor layer disposed on the substrate;
the second gate insulating layer disposed on the second semiconductor layer;
the second gate electrode disposed on the second gate insulating layer; and
the second source electrode and the second drain electrode disposed on the interlayer insulating layer;
a third through-hole and a fourth through-hole, penetrating both the interlayer insulating layer and the second gate insulating layer, respectively, wherein the second source electrode is electrically connected to the second semiconductor layer through the third through-hole, and the second drain electrode is electrically connected to the second semiconductor layer through the fourth through-hole.

Optionally, in some embodiments of the disclosure, an orthographic projection of the channel of the first semiconductor layer on the substrate overlaps an orthographic projection of the first side slope surface on the substrate.

Optionally, in some embodiments of the disclosure, a slope angle between the first side slope surface and the substrate is greater than or equal to 45 degrees and less than or equal to 90 degrees.

Optionally, in some embodiments of the disclosure, the channel of the first semiconductor layer is at least a part of a single crystal grain.

Optionally, in some embodiments of the disclosure, a corner part is formed by an end of the first gate insulating layer corresponding to the first side slope surface close to the substrate, and the channel of the first semiconductor layer covers the corner part.

Optionally, in some embodiments of the disclosure, the first transistor includes a first gate insulating layer, the second transistor includes a second gate insulating layer;

a thickness of the first gate insulating layer is less than a thickness of the second gate insulating layer.

Optionally, in some embodiments of the disclosure, the thickness of the first gate insulating layer ranges from 200 Å to 900 Å, and the thickness of the second gate insulating layer ranges from 1000 Å to 1400 Å.

Optionally, in some embodiments of the disclosure, a material of the first semiconductor layer and a material of the second semiconductor layer are both polysilicon.

Optionally, in some embodiments of the disclosure, the array substrate includes the plurality of first transistors and the plurality of second transistors, and the plurality of first transistors are disposed on a side of the plurality of second transistors.

Optionally, in some embodiments of the disclosure, the high-speed operation module is at least a shift register of a source driver;

the low-speed operation module is at least one of a pixel-driving circuit, a gate driving circuit, a digital-to-analog conversion circuit, an integrated operational amplifier circuit, a latch, a temporary memory, and a level conversion circuit.

### Beneficial Effect

The disclosure provides the array substrate and the display panel, the array substrate includes the substrate, the first cushion layer disposed on the substrate and including the first side slope surface, the second side slope surface opposite to the first side slope surface, and the top surface connected between the first side slope surface and the second side slope surface, the first transistor including the first semiconductor layer disposed on the first side slope surface, and the second transistor including the second semiconductor layer, wherein the channel of the first semiconductor layer is partially located on the first side slope surface, the plane of the channel of the second semiconductor layer is parallel to the substrate, and the electron mobility of the first semiconductor layer is greater than the electron mobility of the second semiconductor layer. In the disclosure, by designing the first semiconductor layer of the first transistor disposed on the first side slope surface of the first cushion layer, since a thickness of the first cushion layer and a length of the first side slope surface are less, a length of the channel of the first semiconductor layer can be designed to be less. In addition, when a material of the first semiconductor layer is polysilicon, in a process of crystallization to form the first semiconductor layer, seed crystals are easier to form at the corner part of an end of the first side slope surface close to the substrate. And when the seed crystals grow along the first side slope surface to form single crystal grains, due to the length of the channel on the first side slope surface being relatively less, a condition for forming the channel composed of the single crystal grains on the first side slope surface can be provided. By designing the first transistor with a less channel length and composed of the single crystal grains, an electron mobility of the first transistor can be improved because of nothingness of grain boundary in the single crystal grains. And at a same time, by designing the first semiconductor layer disposed on the first side slope surface of the first cushion layer and the length of the channel of the first semiconductor layer being less, layout space of the first transistor can be reduced, thus reducing a size of the first transistor. To sum up, compared with conventional transistors such as transistors configured to control sub-pixels, the first transistor provided by the disclosure can be used in system on glass (SOG) technology because of its greater electron mobility and a much smaller size.

### BRIEF DESCRIPTION OF DRAWINGS

In order to explain technical solutions in the embodiments of the disclosure more clearly, the following will briefly introduce the drawings needed to be used in description of the embodiments. Obviously, the drawings in the following description are only some embodiments of the disclosure. For those skilled in the art, other drawings can be obtained from these drawings without paying creative effort.

FIG. 1 is a schematic local top view diagram of an array substrate provided by an embodiment 1 of the disclosure.

FIG. 2 is a schematic sectional diagram taken along a dotted line A-A in FIG. 1.

FIG. 3 is a schematic sectional diagram taken along a dotted line B-B in FIG. 1.

FIG. 4 is a schematic sectional diagram taken along a dotted line C-C in FIG. 1.

FIG. 5 is a schematic diagram of a display panel provided by an embodiment 2 of the disclosure.

FIG. 6 is a schematic diagram in a first intermediate process of a manufacturing method of an array substrate provided by an embodiment 3 of the disclosure.

FIG. 7 is a schematic diagram in a second intermediate process of the manufacturing method of the array substrate provided by the embodiment 3 of the disclosure.

FIG. 8 is a schematic diagram in a third intermediate process of the manufacturing method of the array substrate provided by the embodiment 3 of the disclosure.

FIG. 9 is a schematic diagram in a fourth intermediate process of the manufacturing method of the array substrate provided by the embodiment 3 of the disclosure.

FIG. 10 is a schematic diagram in a fifth intermediate process of the manufacturing method of the array substrate provided by the embodiment 3 of the disclosure.

### REFERENCE NUMERALS

array substrate 100, display panel 200, high-speed operation module 401, low-speed operation module 402, display area 302, non-display area 301;
first transistor 101, first semiconductor layer 18, channel of the first semiconductor layer 181, first gate electrode 161, first source electrode 201, first drain electrode 202, first gate insulating layer 17, first end 31, second end 32, slope angle α, bottom surface 1614;
second transistor 102, second semiconductor layer 14, channel of the second semiconductor layer 141, second gate insulating layer 15, second source electrode 203, and second drain electrode 204;
substrate 11, first side slope surface 1611, second side slope surface 1613, top surface 1612, interlayer insulating layer 19, first through-hole 2011, second through-hole 2012, third through-hole 2013, fourth through-hole 2014, gate metal layer 16, light-shielding layer 12, first sub-light-shielding layer 121, second sub-light-shielding layer 122, and buffer layer 13.

### DETAILED DESCRIPTION OF EMBODIMENT

In combination with drawings in the embodiments of the disclosure, technical solutions in the embodiments of the disclosure will be described clearly and completely. Obviously, the described embodiments are only part of the embodiments of the disclosure, not all of them. Based on the embodiments of the disclosure, all other embodiments obtained by those skilled in the art without creative effort belong to a scope of the disclosure. In addition, it should be understood that specific embodiments described herein are only used to explain and interpret the disclosure and are not used to limit the disclosure. In the disclosure, location terms used, such as “up” and “down”, generally refer to up and down in actual using or working state of devices, in particular drawing directions in the drawings, unless otherwise described; terms “inside” and “outside” refer to outlines of the devices.

An embodiment of the disclosure provides an array substrate, the array substrate includes a substrate, a first cushion layer disposed on the substrate and including a first side slope surface, a second side slope surface opposite to the first side slope surface, and a top surface connected between the first side slope surface and the second side slope surface, a first transistor including a first semiconductor layer disposed on the first side slope surface, and a second transistor including a second semiconductor layer. A channel of the first semiconductor layer is partially located on the first side slope surface. A plane of a channel of the second semiconductor layer is parallel to the substrate. An electron mobility of the first semiconductor layer is greater than an electron mobility of the second semiconductor layer.

An embodiment of the disclosure also provides a display panel including the array substrate. The following are described in detail. It should be noted that a description order of the following embodiments does not limit a preferred order of the embodiments.

### Embodiment 1

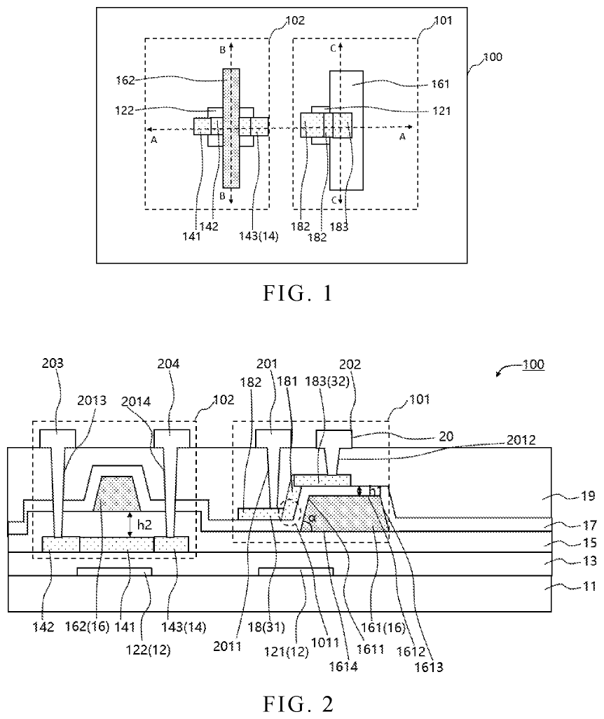

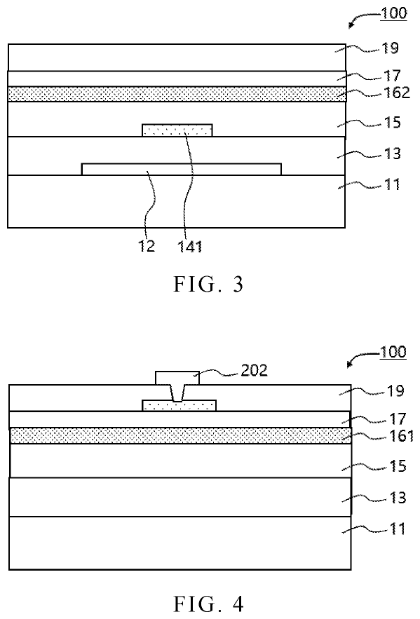

Referring to FIG. 1 to FIG. 4, FIG. 1 is a schematic local top view diagram of an array substrate provided by the embodiment 1 of the disclosure, FIG. 2 is a schematic sectional diagram taken along a dotted line A-A in FIG. 1, FIG. 3 is a schematic sectional diagram taken along a dotted line B-B in FIG. 1, and FIG. 4 is a schematic sectional diagram taken along a dotted line C-C in FIG. 1. A structure of the first transistor and the second transistor disposed adjacent to each other is shown in FIG. 1, a quantity and a location of the first transistor, and a quantity and a location of the second transistor can be designed according to actual demands, which is illustrated here for convenience of explaining a spirit of disclosure.

The embodiment of the disclosure provides an array substrate 100. The array substrate 100 includes a substrate 11, a first cushion layer, a first transistor 101, and a second transistor 102. The first cushion layer is disposed on the substrate 11, and includes a first side slope surface 1611, a second side slope surface 1613 opposite to the first side slope surface 1611, and a top surface 1612 connected between the first side slope surface 1611 and the second side slope surface 1613. The first transistor 101 includes a first semiconductor layer 18 disposed on the first side slope surface 1611, and a channel of the first semiconductor layer 181 is partially located on the first side slope surface 1611. The second transistor 102 includes a second semiconductor layer 14, and a plane of a channel of the second semiconductor layer 141 is parallel to the substrate 11. An electron mobility of the first semiconductor layer 18 is greater than an electron mobility of the second semiconductor layer 14.

Specifically, the substrate 11 may be a glass substrate or a flexible substrate, which is not limited here.

Specifically, the first transistor 101 and the second transistor 102 are disposed on the substrate 11. The first transistor 101 is an unconventional thin-film transistor, the second transistor 102 is a conventional transistor, and the second transistor 102 can be a thin-film transistor configured to drive sub-pixels. The first transistor 101 may be a new thin-film transistor used as an element of integrated circuits. Compared with the second transistor 102, the first transistor 101 has a greater electron mobility and a smaller size, which can meet demands of system on glass (SOG) technology.

Specifically, the top surface 1612 of the first cushion layer is opposite to the substrate 11, and the channel of the first semiconductor layer 181 is partially located on the first side slope surface 1611, so as to make the first transistor 101 an unconventional transistor.

Specifically, the first cushion layer can be a layer specially supporting the first semiconductor layer 18.

Specifically, a cross-sectional shape of the first cushion layer can be trapezoidal, but not limited to this. The top surface 1612 is a surface of the first cushion layer away from the substrate 11, and connected between the first side slope surface 1611 and the second side slope 1613. Shapes of the first side slope surface 1611 and the second side slope 1613 may be linear, arc, or multi-segment linear.

In the embodiment, by designing the first semiconductor layer 18 of the first transistor 101 disposed on the first side slope surface 1611 of the first cushion layer, a length of the channel of the first semiconductor layer 181 can be designed to be less because of both a thickness of the first cushion layer and a length of the first side slope surface 1611 being less. In addition, when a material of the first semiconductor layer 18 is polysilicon, in a process of crystallization to form the first semiconductor layer 18, seed crystals are easier to form at a corner part 1011 of an end of the first side slope surface 1611 close to the substrate 11. When the seed crystals grow along the first side slope surface 1611 to form single crystal grains, due to the length of the channel on the first side slope surface 1611 being relatively less, a condition for forming the channel composed of the single crystal grains on the first side slope surface 1611 can be provided. By designing the first transistor 101 with a less channel length and composed of the single crystal grains, the electron mobility of the first transistor 101 can be improved because of nothingness of grain boundary in the single crystal grains. And at a same time, by designing the first semiconductor layer 18 disposed on the first side slope surface 1611 of the first cushion layer and the length of the channel of the first semiconductor layer 181 being less, layout space of the first transistor 101 can be reduced, thus reducing a size of the first transistor 101. To sum up, compared with conventional transistors such as the second transistor 102 configured to control sub-pixels, the first transistor 101 provided by the embodiment can be used in system on glass (SOG) technology because of its greater electron mobility and a much smaller size.

In some embodiments, the first transistor 101 as a bottom-gate transistor also includes a first gate electrode 161 that is the first cushion layer.

Specifically, the first cushion layer being the first gate electrode 161 means that the first cushion layer can be used as the first gate electrode 161, which can reduce a quantity of film layers of the array substrate 100, thereby reducing steps of a manufacturing process of the array substrate 100 to save manufacturing cost.

Specifically, the first transistor 101 is the bottom-gate transistor, which means that the first cushion layer can be used as the first gate electrode 161. The first semiconductor layer 18 is disposed on the first gate electrode 161 or formed after the first gate electrode 161 is formed.

Specifically, a material of the first gate electrode 161 may be any material in the prior art. For example, the material of the first gate electrode 161 may be one or more of copper, aluminum, titanium, etc., which will not be repeated here.

In some embodiments, the channel of the first semiconductor layer 181 is located between a first end 31 and a second end 32 of the first semiconductor layer 18, the first end 31 is partially located on the substrate 11, and the second end 32 is partially located on the top surface 1612.

Specifically, the first end 31 may include a first heavily doped part and a first lightly doped part connected between the first heavily doped part and the channel of the first semiconductor layer 181. The second end 32 may include a second heavily doped part and a second lightly doped part connected between the second heavily doped part and the channel of the first semiconductor layer 181. The first heavily doped part, the first lightly doped part, the second heavily doped part, and the second lightly doped part have same doped ions as corresponding doped parts in the prior art.

Specifically, the first end 31 is partially located on the substrate 11, and the second end 32 is partially located on the top surface 1612, so as to provide electrical connection space for a first source electrode 201 and a first drain electrode 202.

Specifically, the first end 31 is partially located on the substrate 11, the channel of the first semiconductor layer 181 is partially located on the first side slope surface 1611, and the second end 32 is partially located on the top surface 1612. That is, the first end 31 is located on the substrate 11 and the first side slope surface 1611, or located on the substrate 11. The channel of the first semiconductor layer 181 is partially located on the first side slope surface 1611, or completely located on the first side slope surface 1611. The second end 32 is located on the top surface 1612 and the first side slope surface 1611, or located on the top surface 1612.

In some embodiments, the first transistor 101 also includes a first gate insulating layer 17, the first source electrode 201, and the first drain electrode 202. The array substrate 100 also includes an interlayer insulating layer 19. The first gate insulating layer 17 is disposed on the first gate electrode 161. The first semiconductor layer 18 is disposed on the first gate insulating layer 17. The interlayer insulating layer 19 is disposed on the first semiconductor layer 18. The first source electrode 201 and the first drain electrode 202 are disposed on the interlayer insulating layer 19. A first through-hole 2011 and a second through-hole 2012 penetrating the interlayer insulating layer 19 is further provided. The first source electrode 201 is electrically connected to the first end 31 through the first through-hole 2011, and the first drain electrode 202 is electrically connected to the second end 32 through the second through-hole 2012.

In some embodiments, the second transistor 102 also includes a second gate electrode 162, the first gate electrode 161 and the second gate electrode 162 are disposed in a same layer.

Specifically, the first gate electrode 161 and the second gate electrode 162 are disposed in the same layer, that is, the first gate electrode 161 and the second gate electrode 162 are patterned from a same metal layer. For example, the first gate electrode 161 and the second gate electrode 162 are patterned from the gate metal layer 16, which can reduce a quantity of film layers of the array substrate 100, thereby reducing steps of a manufacturing process of the array substrate 100 to save manufacturing cost.

In some embodiments, the second transistor 102 is a top-gate transistor.

Specifically, a material of the first semiconductor layer 18 and a material of the second semiconductor layer 14 are polysilicon having a characteristic of a high electron mobility. The second transistor 102 as the top-gate transistor can ensure excellent characteristics itself such as a high electron mobility and high reliability. By designing the first transistor 101 being the bottom-gate transistor and the first cushion layer being the first gate electrode 161, the quantity of film layers of the array substrate 100 can be reduced, thereby reducing steps of the manufacturing process of the array substrate 100.

Specifically, the second transistor 102 is the top-gate transistor, the first transistor 101 is the bottom-gate transistor, and the first gate electrode 161 and the second gate electrode 162 are patterned from the same metal layer, and the first semiconductor layer 18 and the second semiconductor layer 14 can be located on two sides of the first gate electrode 161 or the second gate electrode 162, respectively, in this way, the first semiconductor layer 18 and the second semiconductor layer 14 can be formed by different processes without mutual interference.

In some embodiments, the second transistor 102 also includes a second gate insulating layer 15, a second source electrode 203, and a second drain electrode 204. The second semiconductor layer 14 is disposed on the substrate 11. The second gate insulating layer 15 is disposed on the second semiconductor layer 14. The second gate electrode 162 is disposed on the second gate insulating layer 15. The second source electrode 203 and the second drain electrode 204 are disposed on the interlayer insulating layer 19. A third through-hole 2013 and a fourth through-hole 2014 penetrating the interlayer insulating layer 19 and the second gate insulating layer 15 is further provided. The second source electrode 203 is electrically connected to the second semiconductor layer 14 through the third through-hole 2013, and the second drain electrode 204 is electrically connected to the second semiconductor layer 14 through the fourth through-hole 2014.

Specifically, the second source electrode 203 and the second drain electrode 204 are disposed on the interlayer insulating layer 19. That is, the first source electrode 201, the first drain electrode 202, the second source electrode 203, and the second drain electrode 204 are patterned from a same metal layer, which can reduce the quantity of film layers of the array substrate 100, thereby reducing steps of the manufacturing process of the array substrate 100 to save manufacturing cost.

Specifically, the array substrate 100 of the embodiment includes: the substrate 11, the second semiconductor layer 14 disposed on the substrate 11, the second gate insulating layer 15 disposed on the second semiconductor layer 14, the gate metal layer 16 disposed on the second gate insulating layer 15, the first gate insulating layer 17 disposed on the gate metal layer 16, the first semiconductor layer 18 disposed on the first gate insulating layer 17, the interlayer insulating layer 19 disposed on the first semiconductor layer 18, and a source-drain metal layer 20 disposed on the interlayer insulating layer 19. The gate metal layer 16 is patterned to form the first gate electrode 161 and the second gate electrode 162, and the source-drain metal layer 20 is patterned to form the first source electrode 201, the first drain electrode 202, the second source electrode 203, and the second drain electrode 204.

It should be noted that the array substrate 100 may also include a buffer layer 13 located between the second semiconductor layer 14 and the substrate 11, and a light-shielding layer 12 located between the buffer layer 13 and the substrate 11. The light-shielding layer 12 may include a first sub-light-shielding layer 121 and a second sub-light-shielding layer 122. An orthographic projection of the first sub-light-shielding layer 121 on the substrate 11 covers an orthographic projection of the channel of the first semiconductor layer 181 on the substrate 11. An orthographic projection of the second sub-light-shielding layer 122 on the substrate 11 covers an orthographic projection of the channel of the second semiconductor layer 141 on the substrate 11.

Specifically, when the array substrate 100 is a component of a liquid crystal display panel, the array substrate 100 may also include pixel electrodes and common electrodes being same or similar to pixel electrodes and common electrodes in the prior art, and will not be repeated here.

Specifically, the array substrate 100 may also be applied to organic light-emitting diodes (OLEDs) display panels, min light-emitting diodes (Min-LEDs) display panels, micro light-emitting diodes (Micro-LEDs) display panels, or other types of display panels.

Specifically, the array substrate 100 may also be applied to other non-display panels, such as a structure, a component, a terminal, etc.

In some embodiments, the orthographic projection of the channel of the first semiconductor layer 181 on the substrate 11 overlaps an orthographic projection of the first side slope surface 1611 on the substrate 11.

Specifically, the orthographic projection of the channel of the first semiconductor layer 181 on the substrate 11 overlaps the orthographic projection of the first side slope surface 1611 on the substrate 11, that is, the channel of the first semiconductor layer 181 is only located on the first side slope surface 1611, so that the channel of the first semiconductor layer 181 can occupy less layout space to help to reduce a size of the first transistor 101.

In some embodiments, a slope angle α between the first side slope surface 1611 and the substrate 11 is greater than or equal to 45 degrees and less than or equal to 90 degrees.

Specifically, the slope angle α refers to an included angle defined between the first side slope surface 1611 and a plane of the substrate 11 at a position the corner part 1011 located, or an included angle defined between the first side slope surface 1611 and a bottom surface 1614 at the position the corner part 1011 located. The first gate electrode 161 includes the bottom surface 1614, and the bottom surface 1614 is a surface of the first gate electrode 161 close to the substrate 11 or a surface opposite to the top surface 1612.

Specifically, the slope angle α between the first side slope surface 1611 and the substrate 11 may be 45 degrees, 50 degrees, 55 degrees, 60 degrees, 65 degrees, 70 degrees, 75 degrees, 80 degrees, 85 degrees, or 90 degrees.

Specifically, by designing the slope angle α between the first side slope surface 1611 and the substrate 11 being greater than or equal to 45 degrees and less than or equal to 90 degrees, it is conducive to formation of seed crystals at the position the corner part 1011 located. The seed crystals can grow along the first side slope surface 1611, making the channel of the first semiconductor layer 181 more easily composed of single crystal grains.

In some embodiments, the channel of the first semiconductor layer 181 is at least a part of a single crystal grain.

Specifically, the channel of the first semiconductor layer 181 is at least the part of the single crystal grain, due to nothingness of grain boundary in the channel of the first semiconductor layer 181, a carrier mobility of the channel of the first semiconductor layer 181 can be improved, thus improving the electron mobility of the first transistor 101, which is conducive to realizing integration of integrated circuits on the substrate, so as to reduce manufacturing cost of display panels.

In some embodiments, the corner part 1011 is formed by an end of the first gate insulating layer 17 corresponding to the first side slope surface 1611 close to the substrate 11, and the channel of the first semiconductor layer 181 covers the corner part 1011.

Specifically, by designing the channel of the first semiconductor layer 181 covering the corner part 1011, when the material of the first semiconductor layer 18 is polysilicon, in a process of crystallization to form the first semiconductor layer 18, seed crystals are easier to form at the corner part 1011 of the end of the first side slope surface 1611 close to the substrate 11. And when the seed crystals grow along the first side slope surface 1611 to form single crystal grains, due to the length of the channel of the first semiconductor layer 181 on the first side slope surface 1611 being relatively less, a condition for forming the channel composed of the single crystal grains on the first side slope surface 1611 can be provided. And by designing the first transistor 101 with a less channel length and composed of the single crystal grains, the electron mobility of the first transistor 101 can be improved because of nothingness of grain boundary in the single crystal grains.

Specifically, as shown in FIG. 2, the corner part 1011 refers to an end of the first side slope surface 1611 close to the substrate 11, or an end of the first gate insulating layer 17 corresponding to the first side slope surface 1611 close to the substrate 11.

In some embodiments, the first transistor 101 includes the first gate insulating layer 17, and the second transistor 102 includes the second gate insulating layer 15. A thickness of the first gate insulating layer 17 is less than a thickness of the second gate insulating layer 15.

Specifically, when the first transistor 101 is applied to system on glass (SOG) technology, the thickness of the first gate insulating layer 17 can be reduced to further improve the electron mobility of the first transistor 101.

In some embodiments, the thickness of the first gate insulating layer 17 ranges from 200 Å to 900 Å, and the thickness of the second gate insulating layer 15 ranges from 1000 Å to 1400 Å.

In some embodiments, the material of the first semiconductor layer 18 and the material of the second semiconductor layer 14 are both polysilicon.

In some embodiments, the array substrate 100 includes a plurality of the first transistors 101 and a plurality of the second transistors 102, and the plurality of first transistors 101 are disposed on a side of the plurality of second transistors 102.

Specifically, please refer to FIG. 5, and FIG. 5 is a schematic diagram of a display panel provided by an embodiment 2 of the disclosure. The plurality of first transistors 101 are disposed on a side of the plurality of second transistors 102, or the plurality of second transistors 102 are disposed on a side of the plurality of first transistors 101, that is, the plurality of first transistors 101 and the plurality of second transistors 102 are located at different areas of the array substrate 100 or a display panel 200. Under the above-mentioned design, the second semiconductor layer 14 can not be affected when an excimer laser annealing process (ELA) carried out along a first direction X in FIG. 5 is performed on the first semiconductor layer 18. At a same time, the first semiconductor layer 18 can not be affected when the ELA is performed on the the second semiconductor layer 14. Therefore, performances of the first semiconductor layer 18 and the second semiconductor layer 14 can be improved.

### Embodiment 2

Please refer to FIG. 5, and FIG. 5 is the schematic diagram of the display panel provided by the embodiment 2 of the disclosure.

An embodiment of the disclosure also provides the display panel 200. The display panel 200 includes the array substrate 100 provided by the above-mentioned embodiment. The display panel 200 includes a high-speed operation module 401 and a low-speed operation module 402. The high-speed operation module 401 includes a plurality of first transistors 101, and the low-speed operation module 402 includes a plurality of second transistors 102.

Specifically, the high-speed operation module 401 refers to a structure or a component including the first transistor 101, or a structure or a component having a higher electron mobility. The low-speed operation module 402 refers to a structure or component including the second transistor 102, or a structure or a component having a lower electron mobility.

In some embodiments, the high-speed operation module 401 is at least a shift register of a source driver. The low-speed operation module 402 is at least one of a pixel-driving circuit Pixel 1, a gate driving circuit, a digital-to-analog conversion circuit, an integrated operational amplifier circuit, a latch, a temporary memory, and a level conversion circuit.

In FIG. 5, the display panel 200 includes a display area 302 and a non-display area 301, and the high-speed operation module 401 is located on a side of the low-speed operation module 402.

### Embodiment 3

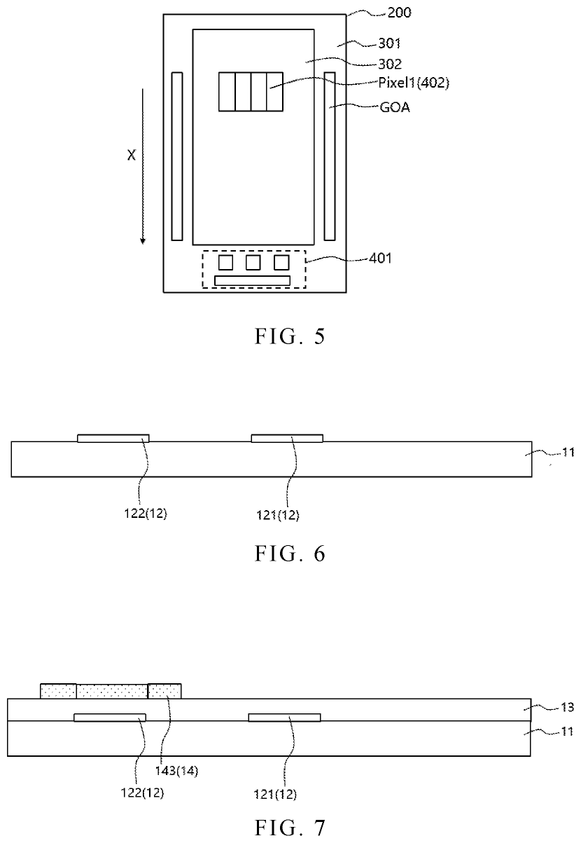

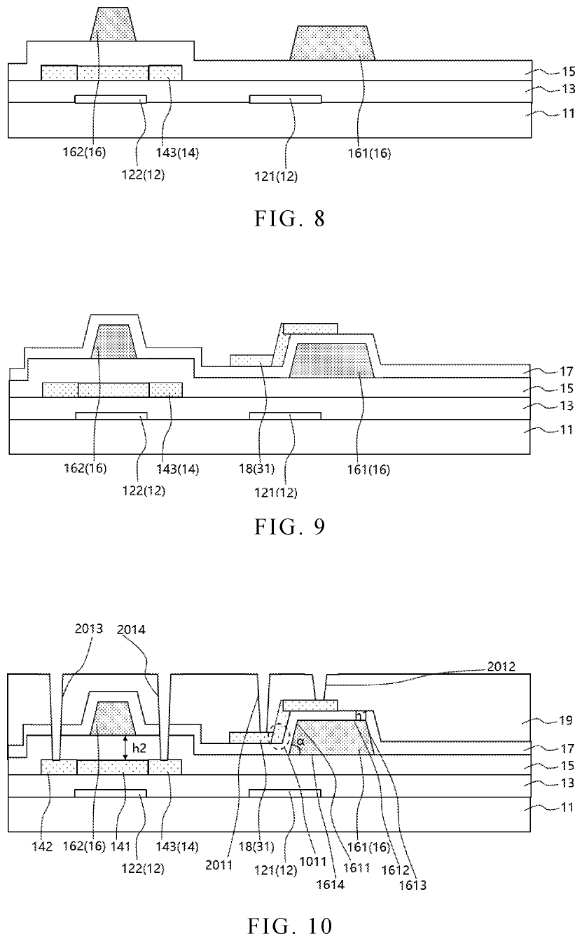

Please refer to FIG. 6 to FIG. 10, FIG. 6 is a schematic diagram in a first intermediate process of a manufacturing method of an array substrate provided by the embodiment 3 of the disclosure, FIG. 7 is a schematic diagram in a second intermediate process of the manufacturing method of the array substrate provided by the embodiment 3 of the disclosure, FIG. 8 is a schematic diagram in a third intermediate process of the manufacturing method of the array substrate provided by the embodiment 3 of the disclosure, FIG. 9 is a schematic diagram in a fourth intermediate process of the manufacturing method of the array substrate provided by the embodiment 3 of the disclosure, and FIG. 10 is a schematic diagram in a fifth intermediate process of the manufacturing method of the array substrate provided by the embodiment 3 of the disclosure.

An embodiment of the disclosure also provides a manufacturing method of the above-mentioned array substrate or the above-mentioned display panel. The array substrate 100 or the display panel 200 in any of the above-mentioned embodiments can be manufactured by using the manufacturing method of the array substrate or the display panel of the embodiment.

Manufacturing steps of the manufacturing method of the array substrate or the display panel include a step S100, a step S200, a step S300, a step S400, a step S500, and a step S600.

The step S100: providing the substrate 11, forming the light-shielding layer 12 on the substrate 11, and forming the first sub-light-shielding layer 121 and the second sub-light-shielding layer 122 by patterning the light-shielding layer 12, as shown in FIG. 6.

The step S200: forming the buffer layer 13 on the light-shielding layer 12, and forming the second semiconductor layer 14 on the buffer layer 13, as shown in FIG. 7.

The step S300: forming the second gate insulating layer 15 on the second semiconductor layer 14, forming the gate metal layer 16 on the second gate insulating layer 15, and forming the first gate electrode 161 and the second gate electrode 162 by patterning the gate metal layer 16, as shown in FIG. 8.

The step S400: forming the first gate insulating layer 17 on the gate metal layer 16, and forming the first semiconductor layer 18 on the first gate insulating layer 17, as shown in FIG. 9.

The step S500: as shown in FIG. 10, forming the interlayer insulating layer 19 on the first semiconductor layer 18, and defining the first through-hole 2011, the second through-hole 2012, the third through-hole 2013, and the fourth through-hole 2014 while forming the interlayer insulating layer 19, as shown in FIG. 10.

The step S600: forming the source-drain metal layer 20 on the interlayer insulating layer 19, and forming the first source electrode 201, the first drain electrode 202, the second source electrode 203, and the second drain electrode 204 by patterning the source-drain metal layer 20, as shown in FIG. 2.

Specifically, in the manufacturing method of the array substrate, film layers or structures of the first transistor 101 and the second transistor 102 are same as film layers or structures in the above-mentioned array substrate provided by the embodiment 1, which will not be repeated here.

The array substrate and the display panel provided by the embodiments of the disclosure are described in detail. In this paper, specific embodiments are adopted to illustrate a principle and implementation modes of the disclosure. The description of the above-mentioned embodiments is only used to help understand methods and a core idea of the disclosure. At the same time, for those skilled in the art, according to the idea of the disclosure, there will be changes in specific implementation modes and a scope of the disclosure. In conclusion, contents of the specification should not be interpreted as a limitation of the disclosure.

What is claimed is:

1. An array substrate, comprising:
a substrate;
a first cushion layer, disposed on the substrate, and comprising a first side slope surface, a second side slope surface opposite to the first side slope surface, and a top surface connected between the first side slope surface and the second side slope surface;
a first transistor, comprising a first semiconductor layer disposed on the first side slope surface, wherein a channel of the first semiconductor layer is partially located on the first side slope surface; and
a second transistor, comprising a second semiconductor layer, wherein a plane of a channel of the second semiconductor layer is parallel to the substrate;
wherein an electron mobility of the first semiconductor layer is greater than an electron mobility of the second semiconductor layer.

2. The array substrate of claim 1, wherein the first transistor as a bottom-gate transistor further comprises a first gate electrode that is the first gate electrode.

3. The array substrate of claim 2, wherein the channel of the first semiconductor layer is located between a first end and a second end of the first semiconductor layer; the first end is partially located on the substrate, and the second end is partially located on the top surface.

4. The array substrate of claim 3, wherein the first transistor further comprises a first gate insulating layer, a first source electrode, and a first drain electrode, and the array substrate further comprises an interlayer insulating layer, and a layer structure of the array substrate comprises:
the first gate insulating layer disposed on the first gate electrode;
the first semiconductor layer disposed on the first gate insulating layer;
the interlayer insulating layer disposed on the first semiconductor layer; and
the first source electrode and the first drain electrode disposed on the interlayer insulating layer;
a first through-hole and a second through-hole, penetrating the interlayer insulating layer, wherein the first source electrode is electrically connected to the first end through the first through-hole, and the first drain electrode is electrically connected to the second end through the second through-hole.

5. A display panel, comprising an array substrate, wherein the array substrate comprises:
a substrate;
a first cushion layer, disposed on the substrate, and comprising a first side slope surface, a second side slope surface opposite to the first side slope surface, and a top surface connected between the first side slope surface and the second side slope surface;
at least one first transistor, comprising a first semiconductor layer disposed on the first side slope surface, wherein a channel of the first semiconductor layer is partially located on the first side slope surface; and
at least one second transistor, comprising a second semiconductor layer, wherein a plane of a channel of the second semiconductor layer is parallel to the substrate;
wherein an electron mobility of the first semiconductor layer is greater than an electron mobility of the second semiconductor layer; and
wherein the display panel further comprises a high-speed operation module and a low-speed operation module, the high-speed operation module comprises a plurality of first transistors, and the low-speed operation module comprises a plurality of second transistors.

6. The display panel of claim 5, wherein the first transistor as a bottom-gate transistor further comprises a first gate electrode that is the first gate electrode.

7. The display panel of claim 6, wherein the channel of the first semiconductor layer is located between a first end and a second end of the first semiconductor layer; the first end is partially located on the substrate, and the second end is partially located on the top surface.

8. The display panel of claim 7, wherein the first transistor further comprises a first gate insulating layer, a first source electrode, and a first drain electrode;
the array substrate further comprises an interlayer insulating layer, and a layer structure of the array substrate includes:
the first gate insulating layer disposed on the first gate electrode;
the first semiconductor layer disposed on the first gate insulating layer;
the interlayer insulating layer disposed on the first semiconductor layer; and
an interlayer insulating layer, disposed on the first semiconductor layer that is on the first gate insulating layer; and
the first source electrode and the first drain electrode disposed on the interlayer insulating layer;
a first through-hole and a second through-hole, penetrating the interlayer insulating layer, wherein the first source electrode is electrically connected to the first end through the first through-hole, and the first drain electrode is electrically connected to the second end through the second through-hole.

9. The display panel of claim 5, wherein the second transistor further comprises a second gate electrode, and the first gate electrode and the second gate electrode are disposed in a same layer.

10. The display panel of claim 9, wherein the second transistor is a top-gate transistor.

11. The display panel of claim 10, wherein the second transistor further comprises a second gate insulating layer, a second source electrode, and a second drain electrode;
a layer structure of the array substrate further comprises:
the second semiconductor layer disposed on the substrate;
the second gate insulating layer disposed on the second semiconductor layer;
the second gate electrode disposed on the second gate insulating layer; and
the second source electrode and the second drain electrode disposed on the interlayer insulating layer;
a third through-hole and a fourth through-hole, penetrating both the interlayer insulating layer and the second gate insulating layer, respectively, wherein the second source electrode is electrically connected to the second semiconductor layer through the third through-hole, and the second drain electrode is electrically connected to the second semiconductor layer through the fourth through-hole.

12. The display panel of claim 8, wherein an orthographic projection of the channel of the first semiconductor layer on the substrate overlaps an orthographic projection of the first side slope surface on the substrate.

13. The display panel of claim 8, wherein a slope angle between the first side slope surface and the substrate is greater than or equal to 45 degrees and less than or equal to 90 degrees.

14. The display panel of claim 8, wherein the channel of the first semiconductor layer is at least a part of a single crystal grain.

15. The display panel of claim 8, wherein a corner part is formed by an end of the first gate insulating layer corresponding to the first side slope surface close to the substrate, and the channel of the first semiconductor layer covers the corner part.

16. The display panel of claim 5, wherein the first transistor comprises a first gate insulating layer, the second transistor comprises a second gate insulating layer, and a thickness of the first gate insulating layer is less than a thickness of the second gate insulating layer.

17. The display panel of claim 16, wherein the thickness of the first gate insulating layer ranges from 200 Å to 900 Å, and the thickness of the second gate insulating layer ranges from 1000 Å to 1400 Å.

18. The display panel of claim 5, wherein a material of the first semiconductor layer and a material of the second semiconductor layer are both polysilicon.

19. The display panel of claim 5, wherein the array substrate comprises the plurality of first transistors and the plurality of second transistors, and the plurality of first transistors are disposed on a side of the plurality of second transistors.

20. The display panel of claim 5, wherein the high-speed operation module is at least a shift register of a source driver, and the low-speed operation module is at least one of a pixel-driving circuit, a gate driving circuit, a digital-to-analog conversion circuit, an integrated operational amplifier circuit, a latch, a temporary memory, and a level conversion circuit.
